(19) United States
(12) Patent Application Publication
(10) Pub. No.: US 2022/0416016 A1
(43) Pub. Date: Dec. 29, 2022

(54) SEMICONDUCTOR DEVICE

(71) Applicant: ROHM CO., LTD., Kyoto (JP)

(72) Inventor: Takeshi ISHIDA, Kyoto (JP)

(73) Assignee: ROHM CO., LTD., Kyoto (JP)

(21) Appl. No.: 17/842,956

(22) Filed: Jun. 17, 2022

(30) Foreign Application Priority Data
Jun. 28, 2021 (JP) 2021-106907

(51) Int. Cl. H01L 29/06; H01L 29/10; H01L 29/78

(52) U.S. Cl. CPC H01L 29/063; H01L 29/1095; H01L 29/7816

(57) ABSTRACT

A semiconductor device includes: a chip having a main surface; a first conductive type first region formed on a surface layer portion of the main surface; a second conductive type second region formed on a surface layer portion of the first region; a drain region formed on a surface layer portion of the second region; a source region formed on the surface layer portion of the first region at a distance from the second region; and a second conductive type floating region formed in the first region at a thickness position between a bottom portion of the first region and a bottom portion of the second region and being spaced apart from the bottom portion of the second region, wherein the floating region faces the second region with a portion of the first region interposed between the floating region and the second region.

### CROSS-REFERENCE TO RELATED APPLICATION

This application is based upon and claims the benefit of priority from Japanese Patent Application No. 2021-106907, filed on Jun. 28, 2021, the entire contents of which are incorporated herein by reference.

### TECHNICAL FIELD

The present disclosure relates to a semiconductor device.

### BACKGROUND

There is known a high withstand voltage P-channel type MOS transistor including an n-type first well diffusion layer, an n-type second well diffusion layer, a p-type third well diffusion layer, a p-type drain diffusion layer, and a p-type source diffusion layer.

### SUMMARY

Some embodiments of the present disclosure provide a semiconductor device capable of suppressing a parasitic capacitance and improving a withstand voltage.

According to one embodiment of the present disclosure, there is provided a semiconductor device including: a chip having a main surface; a first conductive type first region formed on a surface layer portion of the main surface; a second conductive type second region formed on a surface layer portion of the first region; a drain region formed on a surface layer portion of the second region; a source region formed on the surface layer portion of the first region at a distance from the second region; and a second conductive type floating region formed in the first region at a thickness position between a bottom portion of the first region and a bottom portion of the second region and being spaced apart from the bottom portion of the second region, wherein the floating region faces the second region with a portion of the first region interposed between the floating region and the second region.

The above-mentioned or still other objects, features, and effects of the present disclosure will be manifested by embodiments described by reference to the accompanying drawings.

### BRIEF DESCRIPTION OF DRAWINGS

The accompanying drawings, which are incorporated in and constitute a part of the specification, illustrate embodiments of the present disclosure.

FIG. 1 is a plan view showing a semiconductor device according to a first embodiment of the present disclosure.

FIG. 2 is an enlarged view of region II shown in FIG. 1.

FIG. 3 is a cross-sectional view taken along line III-III shown in FIG. 2.

FIG. 4 corresponds to FIG. 3 and is a cross-sectional view showing a semiconductor device according to a first comparative example together with an equipotential distribution.

FIG. 5 corresponds to FIG. 3 and is a cross-sectional view showing a semiconductor device according to a second comparative example together with an equipotential distribution.

FIG. 6 corresponds to FIG. 3 and is a cross-sectional view showing the semiconductor device according to the first embodiment together with an equipotential distribution.

FIG. 7A is a cross-sectional view showing an example of a method of manufacturing the semiconductor device shown in FIG. 1.

FIG. 7B is a cross-sectional view showing a process subsequent to FIG. 7A.

FIG. 7C is a cross-sectional view showing a process subsequent to FIG. 7B.

FIG. 7D is a cross-sectional view showing a process subsequent to FIG. 7C.

FIG. 7E is a cross-sectional view showing a process subsequent to FIG. 7D.

FIG. 7F is a cross-sectional view showing a process subsequent to FIG. 7E.

FIG. 7G is a cross-sectional view showing a process subsequent to FIG. 7F.

FIG. 7H is a cross-sectional view showing a process subsequent to FIG. 7G.

FIG. 7I is a cross-sectional view showing a process subsequent to FIG. 7H.

FIG. 7J is a cross-sectional view showing a process subsequent to FIG. 7I.

FIG. 7K is a cross-sectional view showing a process subsequent to FIG. 7J.

FIG. 7L is a cross-sectional view showing a process subsequent to FIG. 7K.

FIG. 7M is a cross-sectional view showing a process subsequent to FIG. 7L.

FIG. 8 corresponds to FIG. 2 and is a partially enlarged plan view showing a structure of a semiconductor device according to a second embodiment of the present disclosure.

FIG. 9 corresponds to FIG. 2 and is a partially enlarged plan view showing a structure of a semiconductor device according to a third embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Embodiments of the present disclosure will be now described in detail with reference to the accompanying drawings. The accompanying drawings are schematic views and are not exactly illustrated, and the scales thereof and the like do not always match. In addition, the corresponding structures in the accompanying drawings are denoted by the same reference numerals, and duplicate explanation thereof is omitted or simplified. The description given before the omission or simplification applies for structures where the explanation is omitted or simplified.

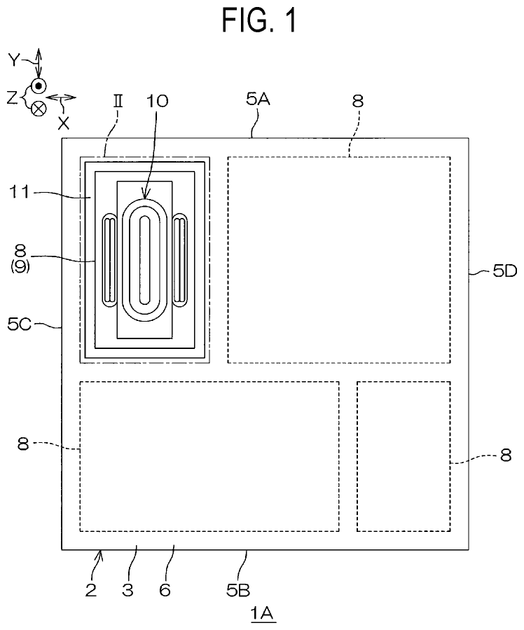

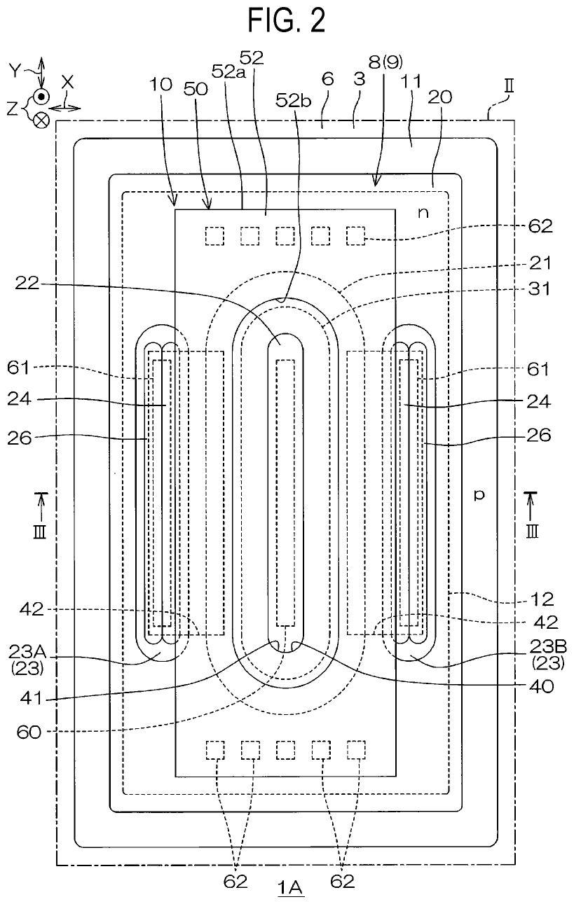

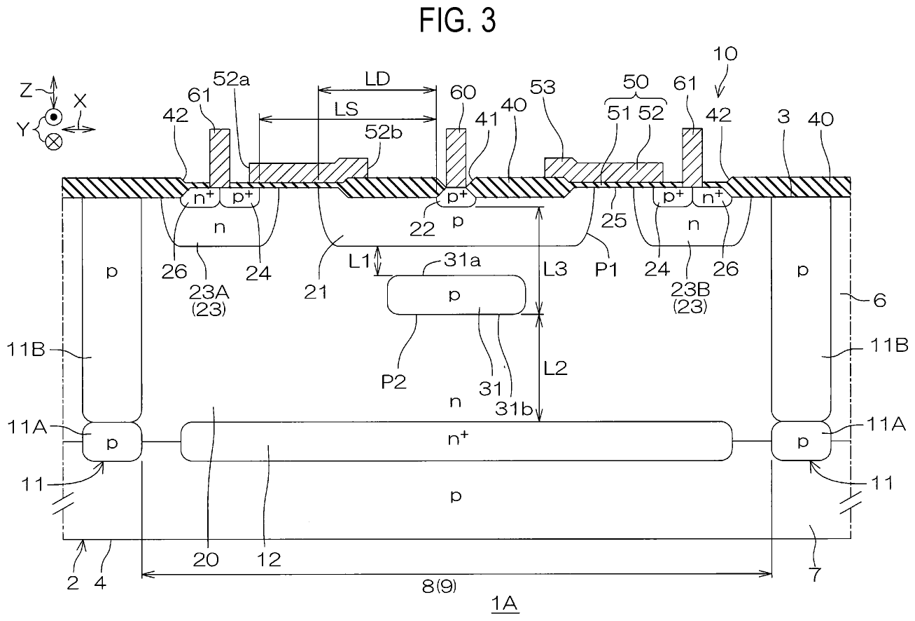

FIG. 1 is a plan view showing a semiconductor device 1A according to a first embodiment of the present disclosure. FIG. 2 is an enlarged view of region II shown in FIG. 1. FIG. 3 is a cross-sectional view taken along line III-III shown in FIG. 3. Referring to FIGS. 1 to 3, the semiconductor device 1A includes a rectangular parallelepiped chip 2 (semiconductor chip). The chip 2 is formed of a silicon chip in this embodiment. The chip 2 has a first main surface 3 on one side, a second main surface 4 on the other side, and first to fourth side surfaces 5A to 5D connecting the first main surface 3 and the second main surface 4.

The first main surface 3 and the second main surface 4 are formed in a quadrilateral shape in a plan view seen from a normal direction Z thereof. The normal direction Z is also a thickness direction of the chip 2. The first side surface 5A and the second side surface 5B extend along a first direction X along the first main surface 3 and face each other along a second direction Y intersecting (specifically, orthogonal to) the first direction X. The third side surface 5C and the fourth side surface 5D extend along the second direction Y and face each other along the first direction X.

The semiconductor device 1A includes an n-type (first conductive type) first semiconductor region 6 formed on a surface layer portion of the first main surface 3 of the chip 2. The first semiconductor region 6 is formed in a layer shape extending along the first main surface 3 and is exposed from the first main surface 3 and the first to fourth side surfaces 5A to 5D. That is, the first semiconductor region 6 has portions of the first main surface 3 and the first to fourth side surfaces 5A to 5D. A concentration of n-type impurities in the first semiconductor region 6 may be 1×10¹⁴ cm⁻³ or more and 1×10¹⁶ cm⁻³ or less. A thickness of the first semiconductor region 6 may be 1 μm or more and 15 μm or less. In this embodiment, the first semiconductor region 6 is formed by an n-type epitaxial layer.

The semiconductor device 1A includes a p-type (second conductive type) second semiconductor region 7 formed on a surface layer portion of the second main surface 4 of the chip 2. The second semiconductor region 7 may be also referred to as a “base region.” The second semiconductor region 7 is formed in a layer shape extending along the second main surface 4 and is exposed from the second main surface 4 and the first to fourth side surfaces 5A to 5D. That is, the second semiconductor region 7 has portions of the second main surface 4 and the first to fourth side surfaces 5A to 5D. The second semiconductor region 7 is connected to the first semiconductor region 6 inside the chip 2.

The second semiconductor region 7 may have a substantially constant p-type impurity concentration in the thickness direction. The concentration of p-type impurities in the second semiconductor region 7 may be 1×10¹³ cm⁻³ or more and 1×10¹⁹ cm⁻³ or less. A thickness of the second semiconductor region 7 may be 50 μm or more and 400 μm or less. The thickness of the second semiconductor region 7 is adjusted by grinding the second main surface 4. In this embodiment, the second semiconductor region 7 is formed by a p-type semiconductor substrate. That is, the chip 2 has a stacked structure including a semiconductor substrate and an epitaxial layer. The second semiconductor region 7 is formed on the semiconductor substrate, and the first semiconductor region 6 is formed on the epitaxial layer.

The semiconductor device 1A includes a plurality of device regions 8 provided in the first semiconductor region 6. In a plan view, the plurality of device regions 8 is partitioned inside the first main surface 3 at a distance from the first to fourth side surfaces 5A to 5D. The number, arrangement, and shape of the device regions 8 are arbitrary and are not limited to a specific number, arrangement, and shape. Each of the plurality of device regions 8 includes various functional devices. The functional devices may include at least one selected from the group of a semiconductor switching device, a semiconductor rectifying device, and a passive device.

The semiconductor switching devices may include at least one selected from the group of a JFET (Junction Field Effect Transistor), a MISFET (Metal Insulator Semiconductor Field Effect Transistor), a BJT (Bipolar Junction Transistor), and an IGBT (Insulated Gate Bipolar Junction Transistor).

The semiconductor rectifying device may include at least one selected from the group of a pn junction diode, a pin junction diode, a Zener diode, a Schottky barrier diode, and a fast recovery diode. The passive device may include at least one selected from the group of a resistor, a capacitor, an inductor, and a fuse.

In this embodiment, the plurality of device regions 8 includes at least one MIS region 9 (see region II in FIG. 1). In this embodiment, the MIS region 9 is a region including at least one transistor cell 10. In this embodiment, the transistor cell 10 includes a p-channel planar gate type LDMISFET (Lateral Double diffused-MISFET). Hereinafter, specific structures of the MIS region 9 and the transistor cell 10 will be described.

Referring to FIGS. 2 and 3, the semiconductor device 1A includes a p-type separation region 11 as an example of a region separation structure for partitioning the MIS region 9 in the first semiconductor region 6. The separation region 11 is formed in an annular shape surrounding a portion of the first main surface 3 in a plan view and partitions the MIS region 9 having a predetermined shape. The separation region 11 electrically separates the MIS region 9 from other regions. In this embodiment, the separation region 11 is formed in a quadrilateral annular shape (specifically, a rectangular annular shape extending in the second direction Y) in a plan view, and partitions the MIS region 9 having a quadrilateral shape (specifically, a rectangular shape extending in the second direction Y) by an inner peripheral edge thereof. The planar shape of the separation region 11 (the planar shape of the MIS region 9) is arbitrary.

The separation region 11 extends from the first main surface 3 toward the second semiconductor region 7 in a wall shape so as to cross the first semiconductor region 6, and is electrically connected to the second semiconductor region 7. In this embodiment, the separation region 11 has a stacked structure including a first layer 11A and a second layer 11B. The first layer 11A is formed at the boundary between the first semiconductor region 6 and the second semiconductor region 7. The first layer 11A is formed at a distance from the first main surface 3 and the second main surface 4 in the normal direction Z and is electrically connected to the second semiconductor region 7. The first layer 11A has a higher p-type impurity concentration than that of the second semiconductor region 7.

The second layer 11B is formed in a region between the first main surface 3 and the first layer 11A in the first semiconductor region 6 and is electrically connected to the first layer 11A. The second layer 11B may have a p-type impurity concentration equal to or lower than the p-type impurity concentration of the first layer 11A. In this embodiment, one second layer 11B is formed, but the number (number of stacks) of the second layer 11B is arbitrary as long as it is electrically connected to the first layer 11A. Therefore, a plurality of second layers 11B may be stacked in the region between the first main surface 3 and the first layer 11A. Of course, the separation region 11 does not necessarily have to have a stacked structure including the first layer 11A and the second layer 11B as long as the MIS region 9 can be partitioned, and the separation region 11 may have a single layer structure composed of a single second layer 11B.

The semiconductor device 1A includes an n-type buried region 12 formed inside the chip 2 so as to cross a bottom portion of the first semiconductor region 6 in the MIS region 9. The buried region 12 may be also referred to as a “first buried region.” Specifically, the buried region 12 is formed at a boundary between the first semiconductor region 6 and the second semiconductor region 7. The buried region 12 has an n-type impurity concentration higher than that of the first semiconductor region 6. The concentration of n-type impurities in the buried region 12 may be 1×10¹⁶ cm⁻³ or more and 1×10¹⁹ cm⁻³ or less.

The buried region 12 is formed at a distance from the first main surface 3 and the second main surface 4 in the normal direction Z and is electrically connected to the first semiconductor region 6. The buried region 12 is formed at a distance from the inner peripheral edge of the separated region 11 in the MIS region 9 and exposes a portion of the second semiconductor region 7 at a peripheral edge portion of the MIS region 9. In this embodiment, the buried region 12 is formed in a quadrilateral shape (specifically, a rectangular shape extending in the second direction Y) along the inner peripheral edge of the separated region 11 in a plan view.

The semiconductor device 1A includes an n-type body region 20 (first region) formed on the surface layer portion of the first main surface 3 in the MIS region 9. In this embodiment, the body region 20 is formed by a portion of the first semiconductor region 6 surrounded by the separation region 11. That is, the body region 20 is composed of a portion of the first semiconductor region 6 and has a bottom portion formed by the bottom portion of the first semiconductor region 6. Further, the body region 20 has a planar shape (in this embodiment, a rectangular shape extending in the second direction Y) consistent with an inner peripheral edge of the separation region 11.

The semiconductor device 1A includes a p-type drift region 21 (second region) formed on a surface layer portion of the body region 20 in the MIS region 9. The drift region 21 has a p-type impurity concentration higher than the n-type impurity concentration of the body region 20 (the first semiconductor region 6). The concentration of p-type impurities in the drift region 21 may be 1×10¹⁵ cm⁻³ or more and 1×10¹⁸ cm⁻³ or less. The drift region 21 may have a concentration gradient in which the p-type impurity concentration gradually decreases in a direction from the surface layer portion of the body region 20 to a bottom portion of the body region 20. It is desirable that the drift region 21 contains boron (B) as p-type impurities.

The drift region 21 is formed at a distance inward from the separation region 11 in a plan view. The drift region 21 is formed in a region surrounded by a peripheral edge of the buried region 12 in a plan view. Specifically, in a plan view, the drift region 21 is formed in the region surrounded by the peripheral edge of the buried region 12 at a distance inward from the peripheral edge of the buried region 12. That is, the entirety of the drift region 21 faces the buried region 12 in a plan view. In this embodiment, the drift region 21 is formed in a band shape extending in the second direction Y in a plan view. Both end portions of the drift region 21 in the second direction Y are curved outward in an arc shape.

The drift region 21 is formed at a distance from the bottom portion of the body region 20 toward the first main surface 3 in the normal direction Z. Specifically, the drift region 21 is formed at a distance from the buried region 12 toward the first main surface 3 in the normal direction Z. The drift region 21 has a cross-sectional shape in which a width thereof in a direction along the first main surface 3 gradually narrows toward the thickness direction. The drift region 21 may have a thickness of 0.5 μm or more and 3 μm or less.

The semiconductor device 1A includes a p-type drain region 22 (first impurity region) formed on a surface layer portion of the drift region 21 in the MIS region 9. The drain region 22 has a p-type impurity concentration higher than that of the drift region 21. The p-type impurity concentration of the drain region 22 may be 1×10¹⁹ cm⁻³ or more and 1×10²¹ cm⁻³ or less. The drain region 22 is formed at a distance inward from a peripheral edge of the drift region 21 in a plan view. In this embodiment, the drain region 22 is formed in a band shape extending along the drift region 21 in a plan view. Both end portions of the drift region 21 in the second direction Y are curved outward in an arc shape. The drain region 22 is formed at a distance from a bottom portion of the drift region 21 toward the first main surface 3 in the thickness direction.

The semiconductor device 1A includes at least one n-type well region 23 (in this embodiment, a plurality of n-type well regions 23) formed on the surface layer portion of the body region 20 in the MIS region 9. Each well region 23 has an n-type impurity concentration greater than the n-type impurity concentration of the body region 20. The concentration of n-type impurities in each well region 23 may be 1×10¹⁶ cm⁻³ or more and 1×10¹⁸ cm⁻³ or less. The well region 23 may have a concentration gradient in which the n-type impurity concentration gradually decreases from a surface layer portion to a bottom portion.

In this embodiment, the plurality of well regions 23 includes a first well region 23A on one side (on a side of the third side surface 5C) and a second well region 23B on the other side (on a side of the fourth side surface 5D). The first well region 23A is formed at a distance from the drift region 21 toward the one side (toward the third side surface 5C) in the first direction X. The second well region 23B is formed at a distance from the drift region 21 toward the other side (toward the fourth side surface 5D) in the first direction X. The second well region 23B faces the first well region 23A with the drift region 21 interposed therebetween. In this embodiment, each of the plurality of well regions 23 is formed in a band shape extending in the second direction Y in a plan view. Both end portions of each of the plurality of well regions 23 in the second direction Y are curved outward in an arc shape.

Each of the plurality of well regions 23 is formed at a distance from the bottom portion of the body region 20 toward the first main surface 3 in the normal direction Z. The plurality of well regions 23 may be formed deeper than the drift region 21 or shallower than the drift region 21. The plurality of well regions 23 may be formed at a distance from the buried region 12 toward the first main surface 3, or may be connected to the buried region 12. Each of the plurality of well regions 23 has a cross-sectional shape in which a width thereof in the direction along the first main surface 3 gradually narrows toward the thickness direction.

The semiconductor device 1A includes a p-type source region 24 (second impurity region) formed on a surface layer portion of each of the plurality of well regions 23 in the MIS region 9. Each source region 24 has a p-type impurity concentration higher than that of the drift region 21. The concentration of p-type impurities in each source region 24 may be 1×10¹⁹ cm⁻³ or more and 1×10²¹ cm⁻³ or less. It is desirable that the p-type impurity concentration of each source region 24 is substantially equal to the p-type impurity concentration of the drain region 22.

Each source region 24 is formed at a distance inward from a peripheral edge of each well region 23 in a plan view. In this embodiment, each source region 24 is formed in a band shape extending along each well region 23 in a plan view. Each source region 24 is formed at a distance from a bottom portion of each well region 23 toward the first main surface 3 in the thickness direction. Each source region 24 faces the drain region 22 in the first direction X, and a channel 25 of the transistor cell 10 is formed between the source region 24 and the drain region 22 (specifically, the drift region 21). Both end portions of each source region 24 in the second direction Y are curved outward in an arc shape.

The semiconductor device 1A includes an n-type contact region 26 formed in a region different from the source region 24 in the surface layer portion of each of the plurality of well regions 23. Each contact region 26 has an n-type impurity concentration higher than that of each well region 23. The concentration of n-type impurities in each contact region 26 may be 1×10¹⁹ cm⁻³ or more and 1×10²¹ cm⁻³ or less.

Each contact region 26 is formed at a distance inward from the peripheral edge of each well region 23 in a plan view. In this embodiment, each contact region 26 is formed in a region opposite to the drain region 22 with respect to each source region 24, and is formed in a band shape extending along each well region 23 in a plan view. Each contact region 26 is formed at a distance from the bottom portion of each well region 23 toward the first main surface 3 in the thickness direction. Both end portions of each contact region 26 in the second direction Y are curved outward in an arc shape.

The semiconductor device 1A includes a p-type floating drift region 31 (floating region) formed inside the body region 20 in the MIS region 9. The floating drift region 31 may also be referred to as a “second buried region” or a “buried drift region.” The floating drift region 31 has a p-type impurity concentration higher than the n-type impurity concentration of the body region 20. The concentration of p-type impurities in the floating drift region 31 may be 1×10¹⁵ cm⁻³ or more and 1×10¹⁸ cm⁻³ or less. It is desirable that a peak value of the p-type impurity concentration of the floating drift region 31 is 0.9 times or more and 1.1 times or less than a peak value of the p-type impurity concentration of the drift region 21. It is desirable that the peak value of the p-type impurity concentration of the floating drift region 31 is substantially equal to the peak value of the p-type impurity concentration of the drift region 21.

That is, it is desirable that a dose amount of p-type impurities for the floating drift region 31 is substantially equal to a dose amount of p-type impurities for the drift region 21. It is desirable that the floating drift region 31 has a concentration gradient in which the p-type impurity concentration gradually decreases in a direction from the bottom portion of the body region 20 toward the surface layer portion of the body region 20. That is, it is desirable that the floating drift region 31 has a concentration that gradually decreases in a direction opposite to a direction in which the concentration of the drift region 21 gradually decreases. It is desirable that the floating drift region 31 contains boron (B) as p-type impurities. That is, it is desirable that the floating drift region 31 contains p-type impurities consisting of the same species as the drift region 21.

The floating drift region 31 is formed inside the body region 20 at a thickness position between the bottom portion of the body region 20 and the bottom portion of the drift region 21. The floating drift region 31 is separated from the bottom portion of the drift region 21 and faces the drift region 21 with a portion of the body region 20 interposed therebetween. The floating drift region 31 is separated from the bottom portion of the body region 20 toward the drift region 21. It is desirable that the floating drift region 31 is formed at a thickness position closer to the bottom portion of the drift region 21 than the bottom portion of the body region 20.

In this embodiment, the floating drift region 31 is separated from the buried region 12 toward the drift region 21 and faces the buried region 12 with a portion of the body region 20 interposed therebetween. The floating drift region 31 is formed at a thickness position closer to the bottom portion of the drift region 21 than the buried region 12. It is desirable that the floating drift region 31 does not face the plurality of well regions 23 in the direction along the first main surface 3 (in this embodiment, the first direction X). That is, it is desirable that the floating drift region 31 is disposed closer to the bottom portion (the buried region 12) of the body region 20 than a depth position of the bottom portions of the plurality of well regions 23.

The floating drift region 31 is formed at a distance inward from the separation region 11 in a plan view. The floating drift region 31 is formed in a region surrounded by the peripheral edge of the buried region 12 in a plan view. Specifically, in a plane view, the floating drift region 31 is formed in a region surrounded by the peripheral edge of the buried region 12 at a distance inward from the peripheral edge of the buried region 12. That is, the entirety of the floating drift region 31 faces the buried region 12 in a plan view.

Further, the floating drift region 31 is formed in a region surrounded by the peripheral edge of the drift region 21 in a plan view. Specifically, the floating drift region 31 is formed in a region surrounded by the peripheral edge of the drift region 21 at a distance inward from the peripheral edge of the drift region 21 in a plan view. That is, the entirety of the floating drift region 31 faces the drift region 21 in a plan view.

The floating drift region 31 faces the drain region 22 in a plan view. It is desirable that the floating drift region 31 faces the entirety of the drain region 22 in a plan view. In this embodiment, the floating drift region 31 is formed in a band shape extending in the second direction Y in a plan view. Both end portions of the floating drift region 31 in the second direction Y are curved outward in an arc shape. It is desirable that the floating drift region 31 has a width smaller than the width of the drift region 21 in the first direction X. The floating drift region 31 may have a thickness of 0.5 μm or more and 3 μm or less.

The floating drift region 31 has an upper end portion 31a on a side of the surface layer portion of the body region 20 and a lower end portion 31b on a side of the bottom portion of the body region 20. The upper end portion 31a of the floating drift region 31 is formed at a first distance L1 from the bottom portion of the drift region 21. The lower end portion 31b of the floating drift region 31 is formed at a second distance L2 from the buried region 12. It is desirable that the second distance L2 is longer the first distance L1 (L1<L2). The first distance L1 may be 0.1 μm or more and 5 μm or less. It is desirable that the first distance L1 is 0.5 μm or more and 2 μm or less. The second distance L2 may be 0.2 μm or more and 10 μm or less. It is desirable that the second distance L2 is 2 μm or more and 5 μm or less.

The lower end portion 31b of the floating drift region 31 is formed at a third distance L3 from the bottom portion of the drain region 22. It is desirable that the third distance L3 is smaller than a distance LS (L3<LS) between the drain region 22 and the source region 24. That is, it is desirable that when an arc having a radius of the distance LS is drawn around the drain region 22 in a cross-sectional view, the floating drift region 31 is formed so as to be located inside a semicircular region in which at least a part thereof is partitioned by the first main surface 3 and the arc.

It is particularly desirable that the floating drift region 31 is formed so that at least a part or all of the lower end portion 31b is located in the semicircular region. The third distance L3 may be smaller than the width of the drift region 21. The third distance L3 may be within a range of 0.9 times or more and 1.1 times or less than a distance LD between the peripheral edges of the drain region 22 and the drift region 21 (0.9× LD≤L3≤1.1×LD). The third distance L3 may be substantially equal to the distance LD.

The semiconductor device 1A includes a first pn junction P1 and a second pn junction P2. The first pn junction P1 is formed at a boundary between the body region 20 and the drift region 21. The first pn junction P1 expands a first depletion layer to the body region 20 and the drift region 21. The second pn junction P2 is formed at a boundary between the body region 20 and the floating drift region 31. The second pn junction P2 expands a second depletion layer to the body region 20 and the floating drift region 31.

The second depletion layer from the second pn junction P2 is connected to the first depletion layer from the first pn junction P1 in a region between the drift region 21 and the floating drift region 31 in the body region 20. That is, the drift region 21 is configured to expand the first depletion layer from the boundary with the body region 20 into the body region 20. On the other hand, the floating drift region 31 is configured to expand the second depletion layer from the boundary with the body region 20 into the body region 20 so that the second depletion layer is connected to the first depletion layer from the drift region 21.

The semiconductor device 1A includes a field insulating film 40 that selectively covers the first main surface 3 inside and outside the MIS region 9. It is desirable that the field insulating film 40 includes a silicon oxide film. The field insulating film 40 covers the periphery of the drain region 22 (the inner portion of the drift region 21) and the separation region 11 on the first main surface 3. The field insulating film 40 includes a first opening 41 and a plurality of second openings 42. The first opening 41 exposes the drain region 22. In this embodiment, the first opening 41 is formed in a band shape (oval shape) extending along the drain region 22 in a plan view.

One second opening 42 is formed in a region between the drain region 22 and the first well region 23A and exposes the channel 25 on a side of the first well region 23A. Another second opening 42 is formed in a region between the drain region 22 and the second well region 23B and exposes the channel 25 on a side of the second well region 23B. Specifically, each second opening 42 exposes the peripheral edge portion of the drift region 21, the well region 23, the source region 24, and the contact region 26. In this embodiment, each second opening 42 is formed in a band shape (rectangular shape) extending along the drift region 21 in a plan view.

The semiconductor device 1A includes a planar gate structure 50 formed on the first main surface 3 so as to cover the channel 25 in the MIS region 9. The planar gate structure 50 controls on/off of the channel 25. The planar gate structure 50 has a stacked structure including a gate insulating film 51 and a gate electrode 52. It is desirable that the gate insulating film 51 includes a silicon oxide film. It is desirable that the gate electrode 52 contains conductive polysilicon.

The gate insulating film 51 is formed in each of the plurality of second openings 42 of the field insulating film 40 and covers a region (i.e., the channel 25) between the drain region 22 and the source region 24 in the second openings 42. Specifically, the gate insulating film 51 covers the peripheral edge portion of the drift region 21, the body region 20, the peripheral edge portion of the well region 23, the source region 24, and the contact region 26 in each of the second openings 42. The gate insulating film 51 has a thickness smaller than a thickness of the field insulating film 40 and is connected to the field insulating film 40.

The gate electrode 52 is formed on the gate insulating film 51 and faces the region (i.e., the channel 25) between the drain region 22 and the source region 24 with the gate insulating film 51 interposed therebetween. Specifically, the gate electrode 52 is formed in each of the plurality of second openings 42 of the field insulating film 40 and faces the channel 25 with the gate insulating film 51 interposed therebetween in the second openings 42. Specifically, the gate electrode 52 faces the peripheral edge portion of the drift region 21, the body region 20, the peripheral edge portion of the well region 23, and the source region 24 with the gate insulating film 51 interposed therebetween in each of the second openings 42.

In this embodiment, the gate electrode 52 is formed in an annular shape surrounding the drain region 22 in a plan view. The gate electrode 52 includes an outer peripheral wall 52a on a side of the separation region 11 and an inner peripheral wall 52b on a side of the drain region 22. The outer peripheral wall 52a is formed at a distance from the peripheral edge of the drift region 21 toward the separation region 11 in a plan view and surrounds the drift region 21. In this embodiment, the outer peripheral wall 52a has a planar shape different from the planar shape of the peripheral edge of the drift region 21 in a plan view. In this embodiment, the outer peripheral wall 52a is formed in a rectangular shape extending along the inner peripheral edge of the separation region 11. Of course, the outer peripheral wall 52a may be formed in an oval shape extending along the separation region 11 in a plan view.

The inner peripheral wall 52b is formed at a distance from the peripheral edge of the drift region 21 toward the drain region 22 in a plan view and surrounds the drain region 22. In this embodiment, the inner peripheral wall 52b is formed at a distance from the peripheral edge of the floating drift region 31 toward the peripheral edge side of the drift region 21 and surrounds the floating drift region 31. Of course, the inner peripheral wall 52b may be formed at a distance from the peripheral edge of the floating drift region 31 toward the peripheral edge of the drift region 21 in a plan view.

That is, the inner peripheral wall 52b may be located in a region between the peripheral edge of the floating drift region 31 and the peripheral edge of the drift region 21 in a plan view. In this embodiment, the inner peripheral wall 52b has a planar shape similar to the planar shape of the peripheral edge of the floating drift region 31 in a plan view. In this embodiment, the inner peripheral wall 52b is formed in an oval shape extending along the floating drift region 31 in a plan view. Of course, the inner peripheral wall 52b may be formed in a rectangular shape extending along the inner peripheral edge of the floating drift region 31 in a plan view.

In this embodiment, the gate electrode 52 includes a drawing portion 53 drawn from above the gate insulating film 51 onto the field insulating film 40. The drawing portion 53 forms the inner peripheral wall 52b of the gate electrode 52. The drawing portion 53 is formed at a distance from the drain region 22 toward a side of the peripheral edge portion of the drift region 21 in a plan view and faces the drift region 21 with the field insulating film 40 interposed therebetween.

As described above, the transistor cell 10 includes the drift region 21, the drain region 22, the plurality of (two) well regions 23, the plurality of (two) source regions 24, the plurality of (two) contact regions 26, and the planar gate structure 50.

The semiconductor device 1A includes a drain contact electrode 60, a plurality of source contact electrodes 61, and a gate contact electrode 62. The drain contact electrode 60 is electrically connected to the drain region 22 on the first main surface 3. The drain contact electrode 60 may be formed in a band shape extending along the drain region 22 in a plan view.

The plurality of source contact electrodes 61 cover the plurality of well regions 23 on the first main surface 3, respectively, and are electrically connected to the source region 24 and the contact region 26 in the plurality of well regions 23, respectively. The plurality of source contact electrodes 61 may be formed in a band shape extending along the plurality of well regions 23 in a plan view.

The gate contact electrode 62 is electrically connected to the gate electrode 52 on the planar gate structure 50. The gate contact electrode 62 is electrically connected to either or both of both end portions of the gate electrode 52 in the second direction Y. It is desirable that the gate contact electrode 62 faces the field insulating film 40 with the drawing portion 53 of the gate electrode 52 interposed therebetween.

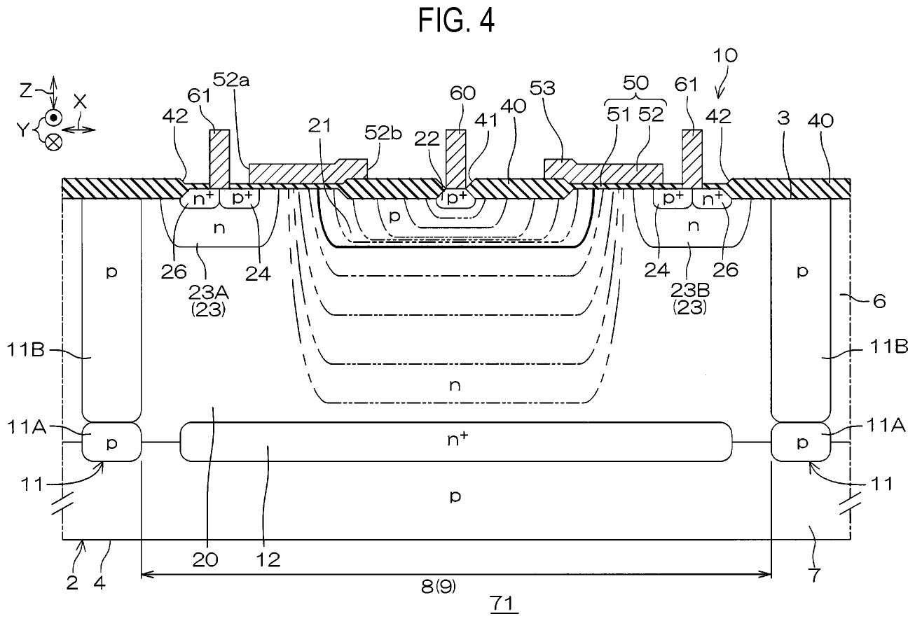

FIG. 4 corresponds to FIG. 3 and is a cross-sectional view showing a semiconductor device 71 according to a first comparative example together with an equipotential distribution. Referring to FIG. 4, the semiconductor device 71 according to the first comparative example has the same structure as the semiconductor device 1A according to the first embodiment except that the former does not have the floating drift region 31. In the semiconductor device 71, equipotential lines become dense in the vicinity of the bottom portion of the drift region 21. That is, in the semiconductor device 71, a withstand voltage (specifically, a breakdown voltage) decreases due to the electric field concentration at the bottom portion of the drift region 21.

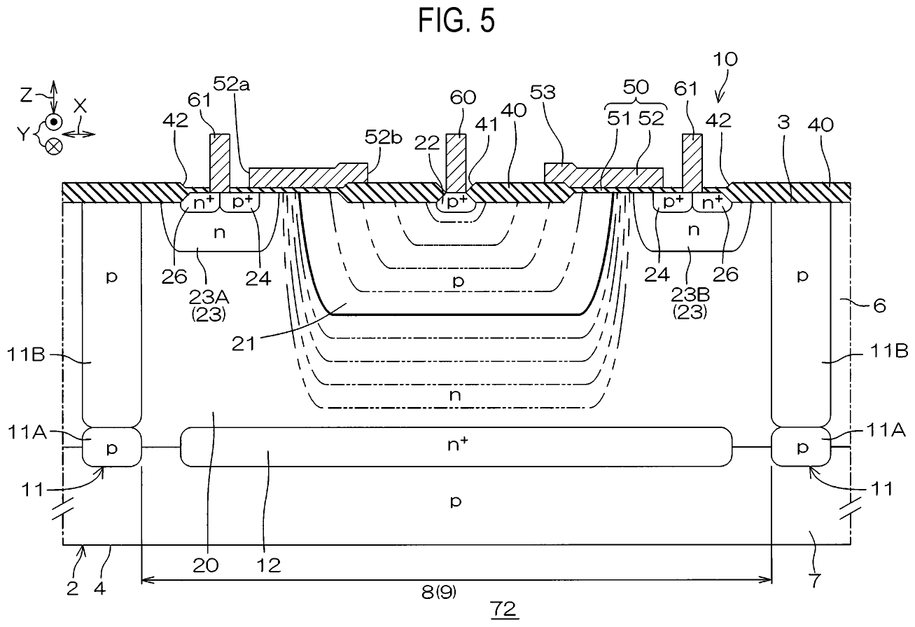

FIG. 5 corresponds to FIG. 3 and is a cross-sectional view showing a semiconductor device 72 according to a second comparative example together with an equipotential distribution. Referring to FIG. 5, the semiconductor device 72 according to the second comparative example has the same structure as the semiconductor device 1A according to the first embodiment, except that the former does not have the floating drift region 31 and the drift region 21 is deeply formed. In the semiconductor device 72, equipotential lines are spread in the thickness direction of the body region 20 by the deep drift region 21.

As a result, in the semiconductor device 72, the electric field concentration in the vicinity of the bottom portion of the drift region 21 is suppressed, thereby suppressing a decrease in the withstand voltage due to the electric field concentration. However, in the semiconductor device 72, a parasitic capacitance increases as a result of an increase in a junction area of the drift region 21 with respect to the body region 20. The parasitic capacitance is specifically an output capacitance between the drain region 22 and the source region 24. When the output capacity increases, switching characteristics deteriorate due to a delay in charge/discharge time of the output capacity at on/off times.

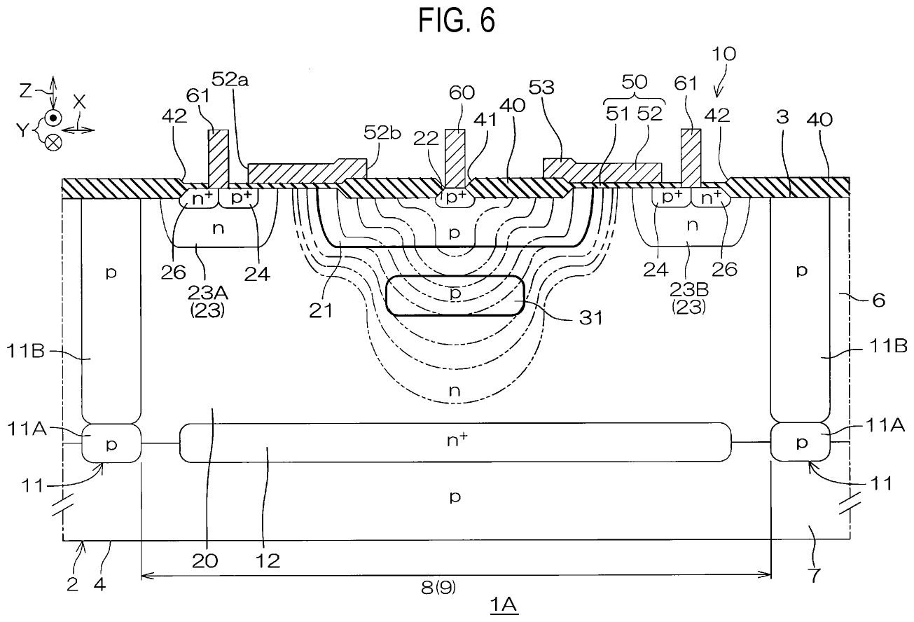

FIG. 6 corresponds to FIG. 3 and is a cross-sectional view showing the semiconductor device 1A according to the first embodiment together with an equipotential distribution. Referring to FIG. 6, the semiconductor device 1A includes the chip 2, the body region 20, the drift region 21, the drain region 22, the source region 24, and the floating drift region 31. The chip 2 has the first main surface 3. The body region 20 is formed on the surface layer portion of the first main surface 3. The drift region 21 is formed on the surface layer portion of the body region 20. The drain region 22 is formed on the surface layer portion of the drift region 21. The source region 24 is formed on the surface layer portion of the body region 20 at a distance from the drift region 21.

The floating drift region 31 is formed in the body region 20 at a thickness position between the bottom portion of the body region 20 and the bottom of the drift region 21, at a distance from the bottom portion of the drift region 21. The floating drift region 31 faces the drift region 21 with a portion of the body region 20 interposed therebetween. According to this structure, the equipotential lines on a side of the drift region 21 are spread in the depth direction of the body region 20 by the floating drift region 31. As a result, the electric field concentration in the vicinity of the bottom portion of the drift region 21 is suppressed, thereby suppressing a decrease in the withstand voltage due to the electric field concentration.

Further, the floating drift region 31 is spaced apart from the drift region 21 with a portion of the body region 20 interposed therebetween. Therefore, a junction area of the drift region 21 with respect to the body region 20 is suppressed from being expanded by a junction area of the floating drift region 31 with respect to the body region 20. As a result, an increase in the output capacity due to an increase in the junction area of the drift region 21 with respect to the body region 20 is suppressed. Therefore, according to the semiconductor device 1A, the withstand voltage can be improved while suppressing the output capacitance (parasitic capacitance).

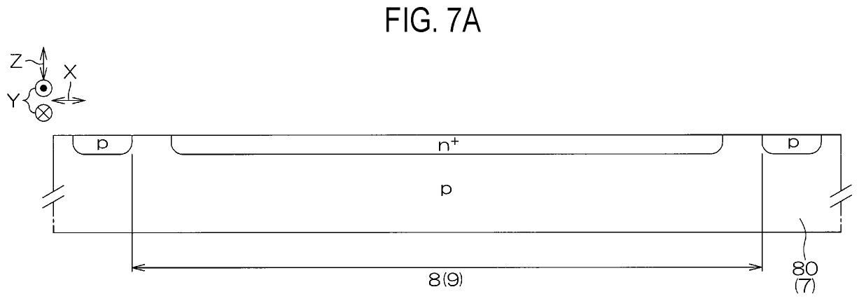

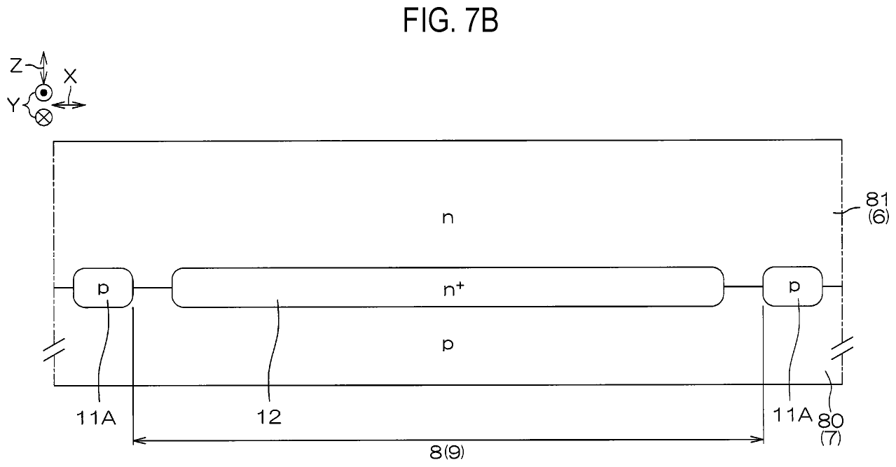

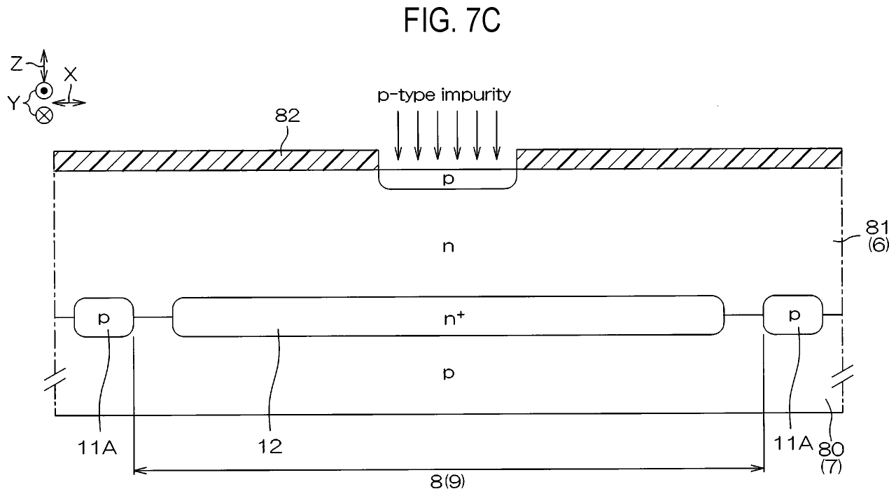

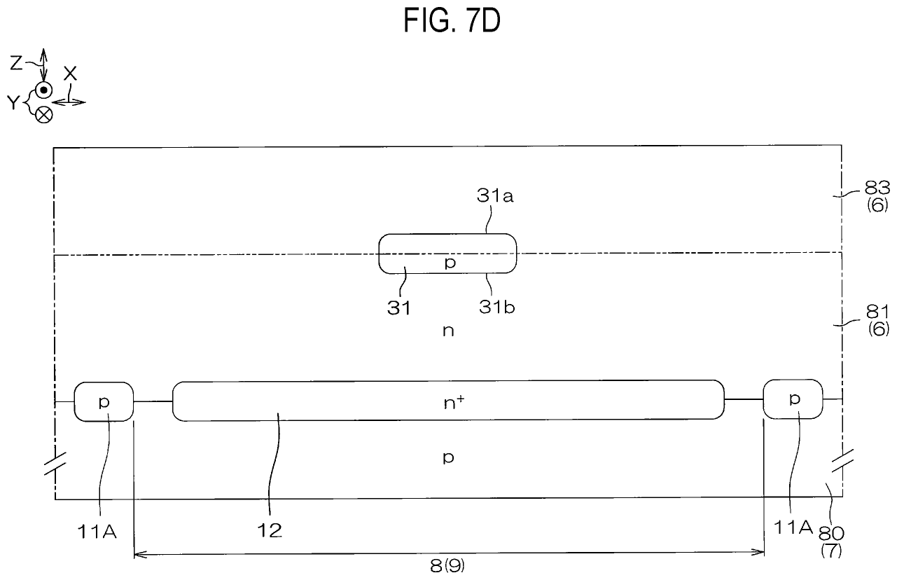

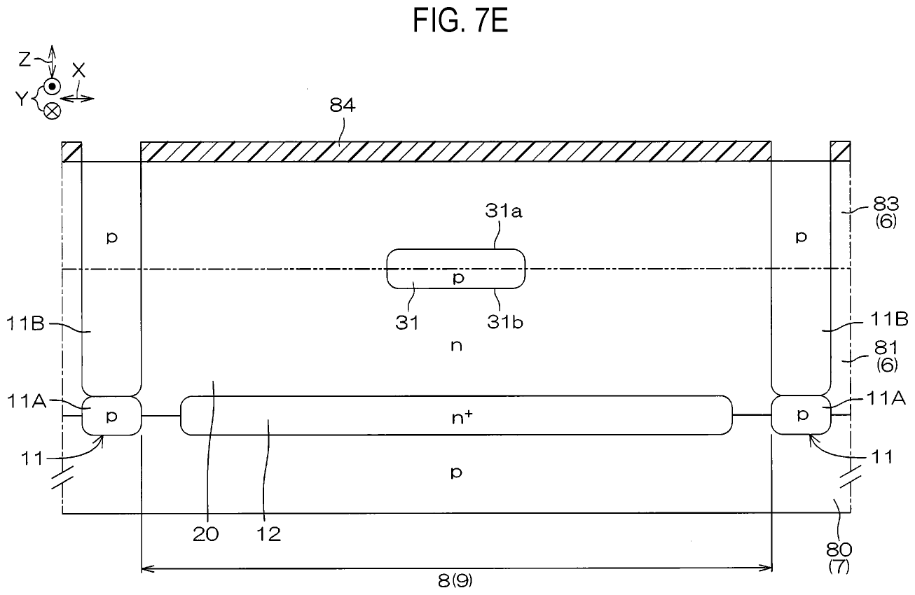

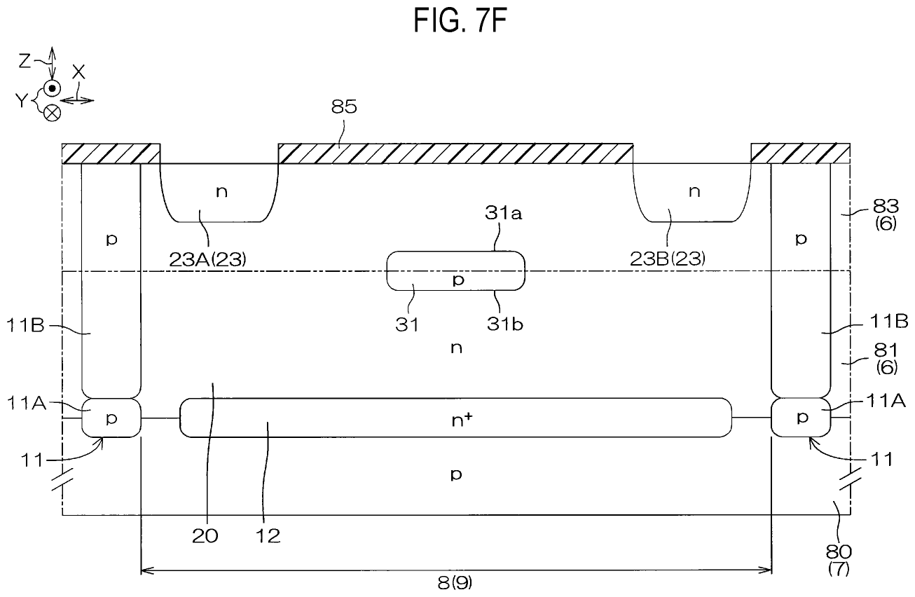

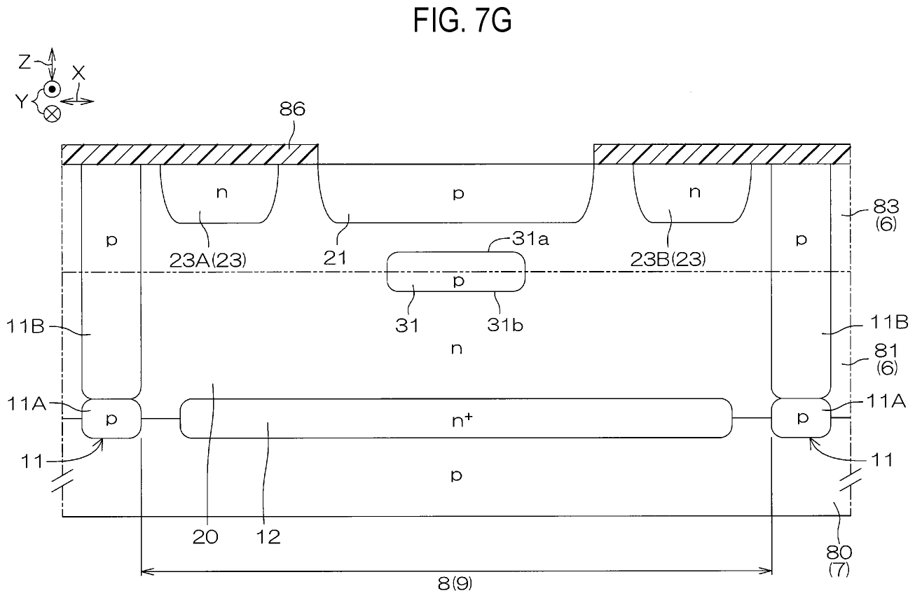

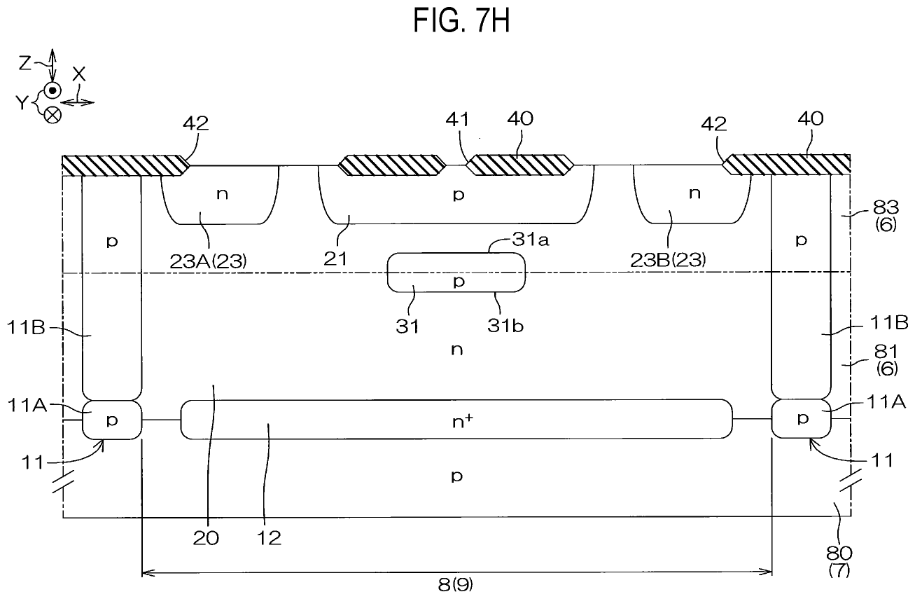

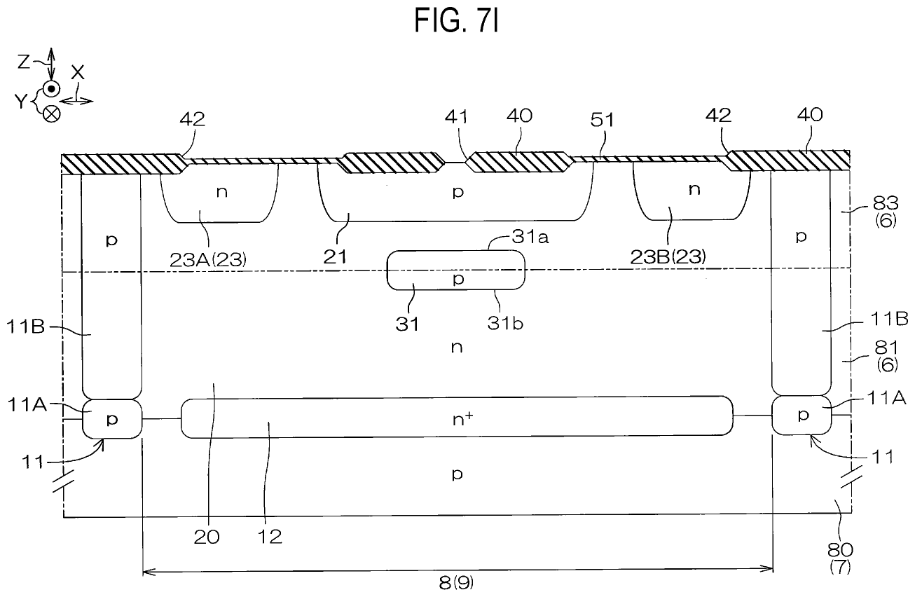

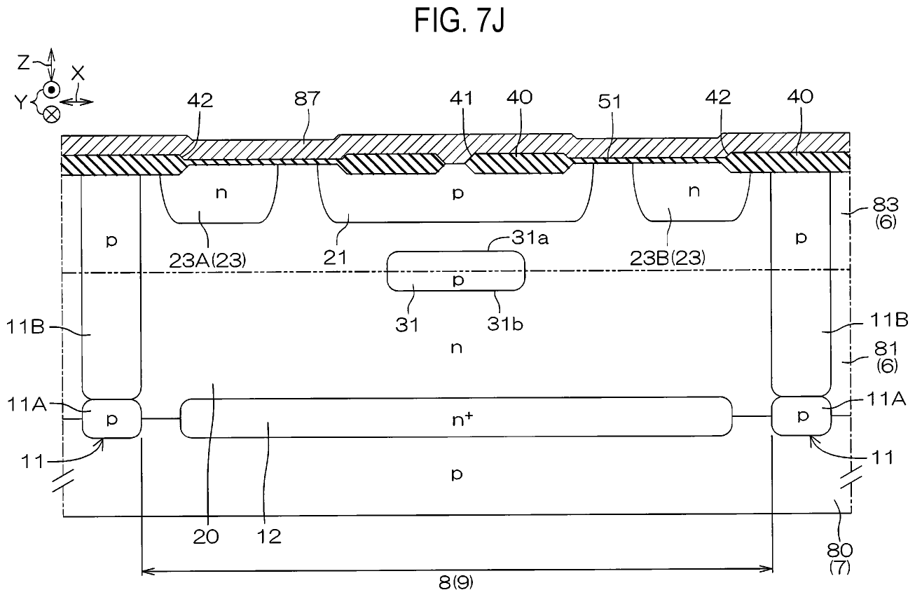

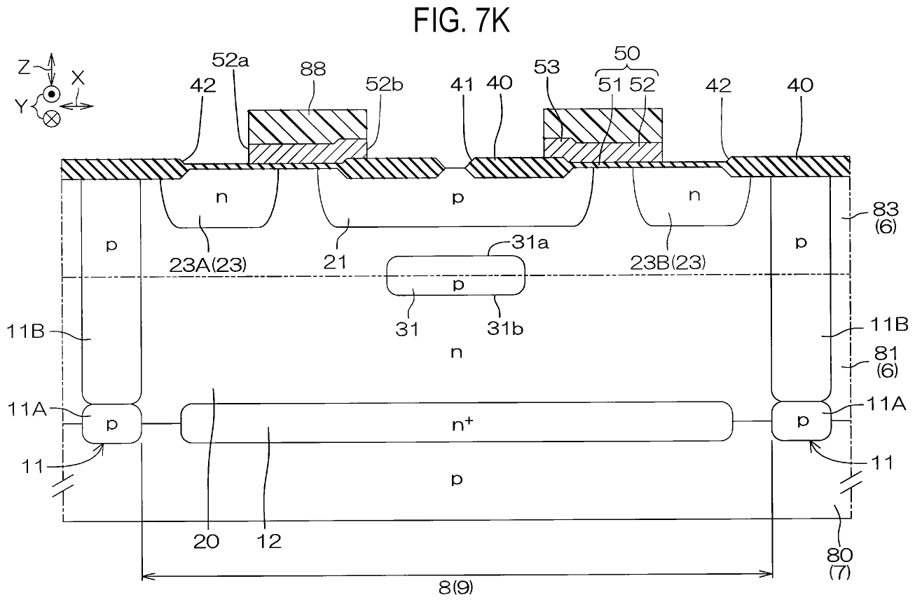

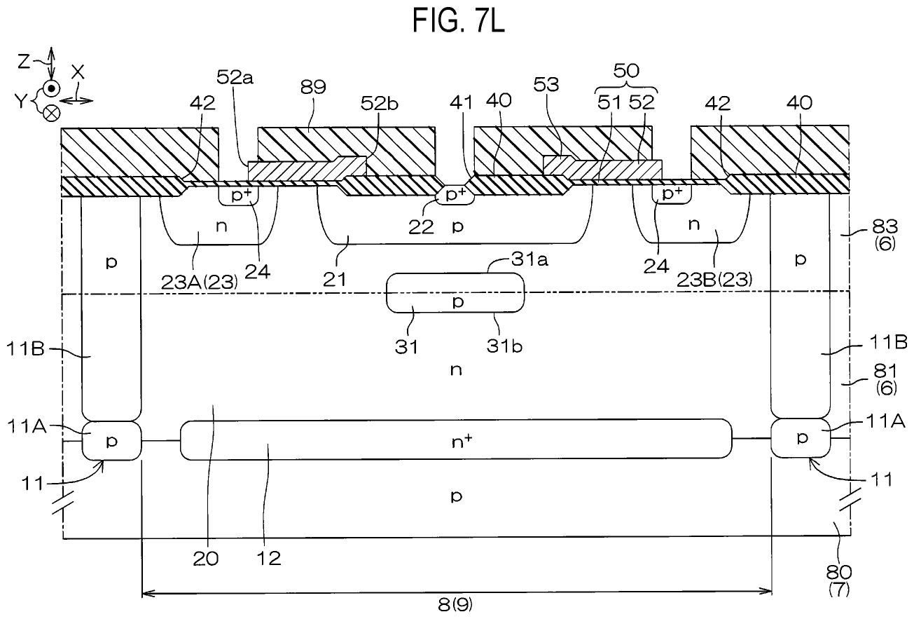

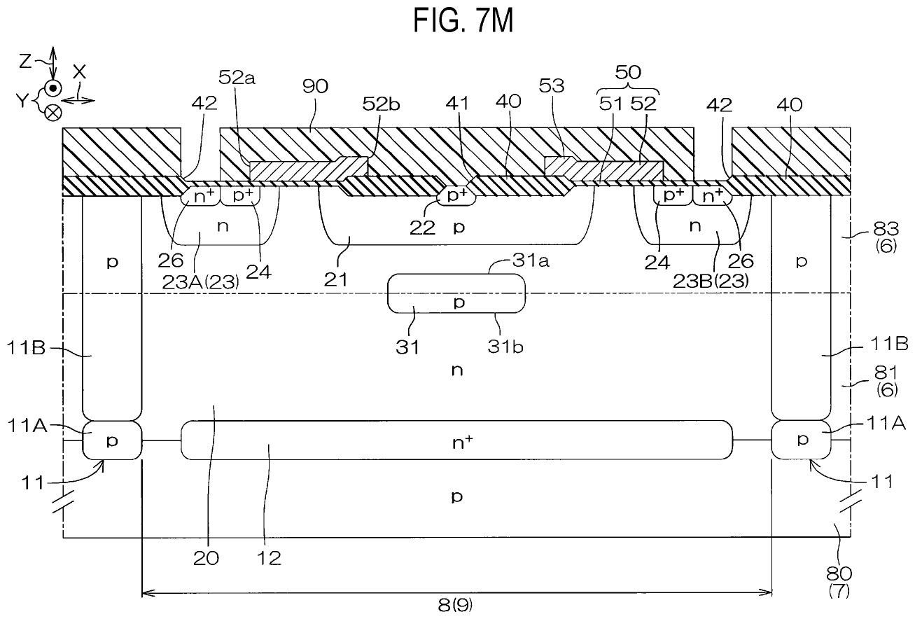

FIGS. 7A to 7M are cross-sectional views showing an example of a method of manufacturing the semiconductor device 1A shown in FIG. 1. Referring to FIG. 7A, a disc-shaped p-type wafer 80 as a base of the second semiconductor region 7 (the semiconductor substrate) is prepared. Subsequently, the MIS region 9 is set on the wafer 80, and p-type impurities are introduced into a region where the first layer 11A of the separation region 11 is to be formed. Further, n-type impurities are introduced into a region in the MIS region 9 where the buried region 12 is to be formed.

Next, referring to FIG. 7B, an n-type first epitaxial layer 81, which becomes a portion of the first semiconductor region 6, is formed on the wafer 80 by an epitaxial growth method. In this process, the n-type impurities and p-type impurities introduced into the wafer 80 diffuse into the wafer 80 and the first epitaxial layer 81 during the crystal growth of silicon. As a result, the first layer 11A of the separation region 11 and the buried region 12 are formed.

Next, referring to FIG. 7C, a first resist mask 82 having a predetermined pattern is formed on the first epitaxial layer 81. The first resist mask 82 exposes a region where the floating drift region 31 is to be formed, and covers the other regions. Subsequently, p-type impurities are introduced into a surface layer portion of the first epitaxial layer 81 by an ion implantation method via the first resist mask 82. The first resist mask 82 is then removed.

Next, referring to FIG. 7D, an n-type second epitaxial layer 83, which becomes a portion of the first semiconductor region 6, is formed on the first epitaxial layer 81 by an epitaxial growth method. In this step, the p-type impurities introduced into the first epitaxial layer 81 diffuse into the first epitaxial layer 81 and the second epitaxial layer 83 during the crystal growth of silicon. As a result, the floating drift region 31 is formed.

Next, referring to FIG. 7E, a second resist mask 84 having a predetermined pattern is formed on the first semiconductor region 6. The second resist mask 84 exposes a region where the second layer 11B of the separation region 11 is to be formed, and covers the other regions. Subsequently, p-type impurities are introduced into the first semiconductor region 6 by an ion implantation method via the second resist mask 84. As a result, the separation region 11 including the first layer 11A and the second layer 11B is formed. The second resist mask 84 is then removed.

Next, referring to FIG. 7F, a third resist mask 85 having a predetermined pattern is formed on the first semiconductor region 6. The third resist mask 85 exposes a region where the plurality of well regions 23 is to be formed, and covers the other regions. Subsequently, n-type impurities are introduced into the surface layer portion of the first semiconductor region 6 by an ion implantation method via the third resist mask 85. As a result, the plurality of well regions 23 is formed. The third resist mask 85 is then removed.

Next, referring to FIG. 7G, a fourth resist mask 86 having a predetermined pattern is formed on the first semiconductor region 6. The fourth resist mask 86 exposes a region where the drift region 21 is to be formed, and covers the other regions. Subsequently, p-type impurities are introduced into the surface layer portion of the first semiconductor region 6 by an ion implantation method via the fourth resist mask 86. As a result, the drift region 21 is formed. The process of forming the drift region 21 may be performed prior to the process of forming the plurality of well regions 23. The fourth resist mask 86 is then removed.

Next, referring to FIG. 7H, the field insulating film 40 is formed on the first semiconductor region 6. The field insulating film 40 is formed by selectively oxidizing the first semiconductor region 6 (the second epitaxial layer 83) by an oxidation treatment method (for example, a thermal oxidation treatment method). The field insulating film 40 has the first opening 41 that exposes the inner portion of the drift region 21, and the plurality of second openings 42 that exposes the plurality of well regions 23. The first opening 41 exposes a region where the drain region 22 is to be formed, and the plurality of second openings 42 exposes regions where the source region 24 and the contact region 26 are to be formed, respectively.

Next, referring to FIG. 7I, the gate insulating film 51 is formed on the first semiconductor region 6. The gate insulating film 51 is formed by selectively oxidizing portions in the first semiconductor region 6 exposed from the first opening 41 and the plurality of second openings 42 of the field insulating film 40 by an oxidation treatment method (for example, a thermal oxidation treatment method).

Next, referring to FIG. 7J, a base electrode layer 87, which becomes the gate electrode 52, is formed on the field insulating film 40 and the gate insulating film 51. The base electrode layer 87 contains conductive polysilicon. The base electrode layer 87 may be formed by a CVD (Chemical Vapor Deposition) method.

Next, referring to FIG. 7K, a fifth resist mask 88 having a predetermined pattern is formed on the base electrode layer 87. The fifth resist mask 88 covers a region where the gate electrode 52 is to be formed, and exposes the other regions. Subsequently, an unnecessary portion of the base electrode layer 87 is removed by an etching method via the fifth resist mask 88. The etching method may be a wet etching method and/or a dry etching method. As a result, the gate electrode 52 is formed. The fifth resist mask 88 is then removed.

Next, referring to FIG. 7L, a sixth resist mask 89 having a predetermined pattern is formed on the field insulating film 40 and the gate electrode 52. The sixth resist mask 89 exposes a region where the drain region 22 and the plurality of source regions 24 are to be formed, and covers the other regions. Subsequently, p-type impurities are introduced into the surface layer portion of the first semiconductor region 6 by an ion implantation method via the sixth resist mask 89.

As a result, the drain region 22 and the plurality of source regions 24 are formed. In this embodiment, the drain region 22 is formed in a self-aligned manner with respect to the first opening 41 of the field insulating film 40. In this embodiment, the plurality of source regions 24 is formed in a self-aligned manner with respect to a portion (a portion extending in the second direction Y) of the outer peripheral wall 52a of the gate electrode 52. The sixth resist mask 89 is then removed.

Next, referring to FIG. 7M, a seventh resist mask 90 having a predetermined pattern is formed on the field insulating film 40 and the gate electrode 52. The seventh resist mask 90 exposes regions where the plurality of contact regions 26 is to be formed, and covers the other regions. Subsequently, n-type impurities are introduced into the surface layer portion of the first semiconductor region 6 by an ion implantation method via the seventh resist mask 90. As a result, the plurality of contact regions 26 is formed. In this embodiment, the plurality of contact regions 26 is formed in a self-aligned manner with respect to the plurality of second openings 42 of the field insulating film 40. The process of forming the contact regions 26 may be performed prior to the process of forming the drain region 22 and the source region 24. The seventh resist mask 90 is then removed.

After that, the drain contact electrode 60, the source contact electrodes 61, and the gate contact electrode 62 are formed. After that, the wafer 80 is selectively cut out, and a plurality of semiconductor devices 1A is diced from the wafer 80. Through the above-described processes, the semiconductor device 1A is manufactured.

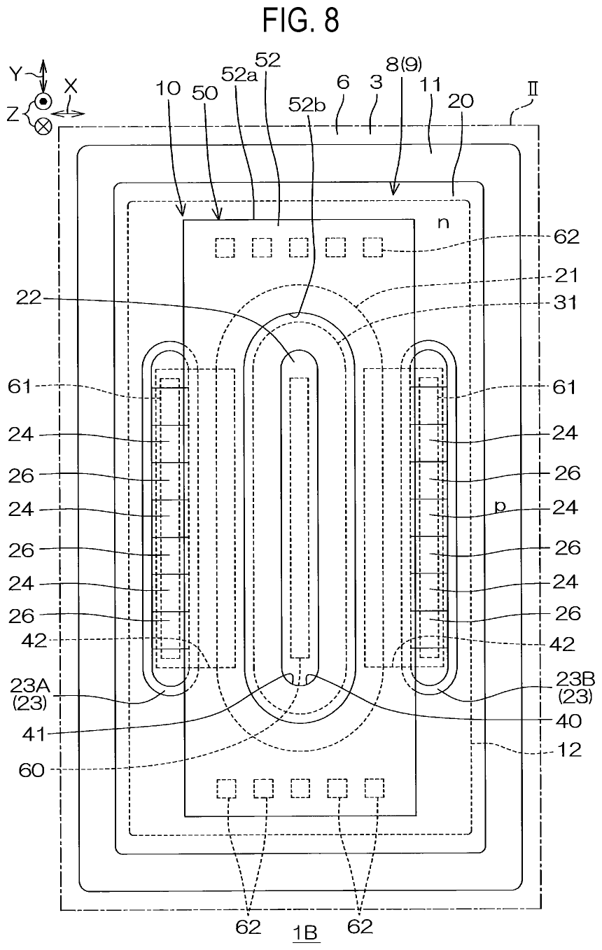

FIG. 8 corresponds to FIG. 2 and is a partially enlarged plan view showing a structure of a semiconductor device 1B according to a second embodiment of the present disclosure. In the semiconductor device 1A according to the first embodiment, the contact region 26 is formed adjacent to the source region 24 in the first direction X in a plan view. On the other hand, referring to FIG. 8, in the semiconductor device 1B according to the second embodiment, the contact region 26 is formed adjacent to the source region 24 in the second direction Y.

Specifically, a plurality of source regions 24 and a plurality of contact regions 26 are formed in each well region 23. The plurality of source regions 24 is formed in each well region 23 at a distance from one another in the second direction Y. Each source region 24 faces the drain region 22 in the first direction X. The plurality of contact regions 26 is formed in each well region 23 at a distance from one another in the second direction Y and alternately with the plurality of source regions 24. From the above, the semiconductor device 1B also has the same effects as the semiconductor device 1A.

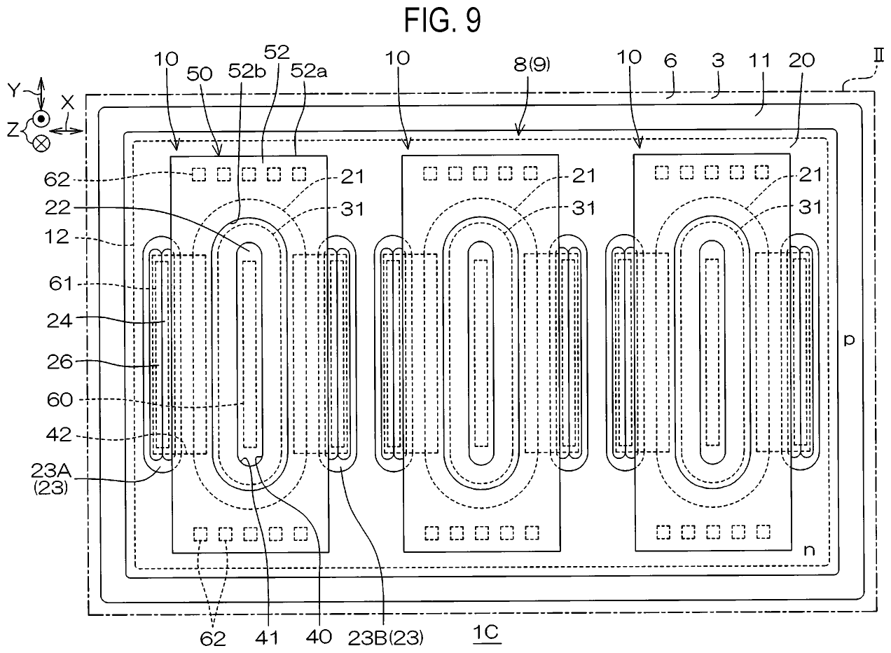

FIG. 9 corresponds to FIG. 2 and is a partially enlarged plan view showing a structure of a semiconductor device 1C according to a third embodiment of the present disclosure. In each of the above-described embodiments, one transistor cell 10 is formed in the MIS region 9. However, a plurality of (two or more) transistor cells 10 may be formed in the MIS region 9. In this case, the separation region 11 may be formed in a quadrilateral annular shape (rectangular shape) extending in the first direction X, the buried region 12 and the body region 20 may be formed in a quadrilateral shape (rectangular shape) extending in the first direction X, and the plurality of transistor cells 10 may be arranged in a row along the first direction X.

Regarding two adjacent transistor cells 10, the first well region 23A of one transistor cell 10 may be integrated with the second well region 23B of the other transistor cell 10. That is, the two adjacent transistor cells 10 may share one well region 23 (including the source region 24 and the contact region 26) located between two adjacent drift regions 21. From the above, the semiconductor device 1C also has the same effects as the semiconductor device 1A.

The present disclosure is implemented in other embodiments. For example, in each of the above-described embodiments, the example in which the second semiconductor region 7 is formed of p-type has been shown. However, the second semiconductor region 7 may be formed of n-type. Further, in each of the above-described embodiments, the example in which the first conductive type is n type and the second conductive type is p type has been described, but the first conductive type may be p type and the second conductive type may be n type. The specific configuration in this case is obtained by replacing the n-type region with the p-type region and replacing the p-type region with the n-type region in the above description and the accompanying drawings.

Examples of the features extracted from the present disclosure and the drawings are shown below. Semiconductor devices capable of suppressing a parasitic capacitance and improving a withstand voltage will be provided below. The alphanumerical characters in parentheses represent the corresponding constituent elements and the like in the above-described embodiments, but are not intended to limit the scope of each item to the embodiments.

[A1] A semiconductor device (1A, 1B, 1C) including: a chip (2) having a main surface (3); a first conductive type first region (20) formed on a surface layer portion of the main surface (3); a second conductive type second region (21) formed on a surface layer portion of the first region (20); a drain region (22) formed on a surface layer portion of the second region (21); a source region (24) formed on the surface layer portion of the first region (20) at a distance from the second region (21), and a second conductive type floating region (31) formed in the first region (20) at a thickness position between a bottom portion of the first region (20) and a bottom portion of the second region (21) and being spaced apart from the bottom portion of the second region (21), wherein the floating region (31) faces the second region (21) with a portion of the first region (20) interposed between the floating region (31) and the second region (21).

[A2] The semiconductor device (1A, 1B, 1C) of A1, wherein the floating region (31) is spaced apart from the bottom portion of the first region (20).

[A3] The semiconductor device (1A, 1B, 1C) of A1 or A2, wherein the floating region (31) is formed at a thickness position closer to the bottom portion of the second region (21) than the bottom portion of the first region (20).

[A4] The semiconductor device (1A, 1B, 1C) of any one of A1 to A3, wherein the second region (21) is configured to expand a first depletion layer from a boundary with the first region (20) into the first region (20), and wherein the floating region (31) is configured to expand a second depletion layer from a boundary with the first region (20) into the first region (20) so that the second depletion layer is connected to the first depletion layer of the second region (21).

[A5] The semiconductor device (1A, 1B, 1C) of any one of A1 to A4, wherein the floating region (31) is formed to be smaller in width than the second region (21).

[A6] The semiconductor device (1A, 1B, 1C) of any one of A1 to A5, wherein an entirety of the floating region (31) faces the second region (21) in a plan view.

[A7] The semiconductor device (1A, 1B, 1C) of any one of A1 to A6, further including a first conductive type well region (23) formed on the surface layer portion of the first region (20) at a distance from the second region (21), wherein the well region (23) has an impurity concentration higher than that of the first region (20), wherein the source region (24) is formed on a surface layer portion of the well region (23).

[A8] The semiconductor device (1A, 1B, 1C) of A7, further including a contact region (26) formed on the surface layer portion of the well region (23) in a region different from the source region (24).

[A9] The semiconductor device (1A, 1B, 1C) of A8, wherein the floating region (31) is formed closer to the bottom portion of the first region (20) than a depth position of a bottom portion of the well region (23), without facing the well region (23) in a direction along the main surface (3).

[A10] The semiconductor device (1A, 1B, 1C) of any one of A1 to A9, further including a first conductive type buried region (12) formed inside the chip (2) so as to cross the bottom portion of the first region (20), wherein the buried region (12) has an impurity concentration higher than that of the first region (20), wherein the floating region (31) is spaced apart from the buried region (12).

[A11] The semiconductor device (1A, 1B, 1C) of A10, wherein the buried region (12) is formed to be larger in width than the second region (21).

[A12] The semiconductor device (1A, 1B, 1C) of any one of A1 to A11, further including: a gate insulating film (51) formed on the main surface (3) to cover a region between the second region (21) and the source region (24); and a gate electrode (52) formed on the gate insulating film (51).

[A13] The semiconductor device (1A, 1B, 1C) of A12, further including a field insulating film (40) formed on the main surface (3) to cover a periphery of the drain region (22), wherein the gate insulating film (51) has a thickness smaller than a thickness of the field insulating film (40) and is connected to the field insulating film (40), and wherein the gate electrode (52) includes a portion (53) that is drawn from above the gate insulating film (51) onto the field insulating film (40).

[A14] The semiconductor device (1A, 1B, 1C) of any one of A1 to A13, further including a second conductive type separation region (11) formed on the surface layer portion of the main surface (3) to partition a device region (8, 9) in a portion of the main surface (3), wherein the first region (20) is formed on the surface layer portion of the main surface (3) in the device region (8, 9).

[A15] The semiconductor device (1A, 1B, 1C) of A14, wherein the separation region (11) is formed in an annular shape surrounding the portion of the main surface (3) in a plan view.

[A16] The semiconductor device (1A, 1B, 1C) of A14 or A15, further including a second conductive type base region (7) formed in a region directly below the first region (20) inside the chip (2), wherein the separation region (11) is electrically connected to the base region (7).

[A17] The semiconductor device (1A, 1B, 1C) of any one of A1 to A16, wherein a distance (L3) between the drain region (22) and the floating region (31) is smaller than a distance (LS) between the drain region (22) and the source region (24) (L3<LS).

[A18] The semiconductor device (1A, 1B, 1C) of any one of A1 to A17, wherein a distance (L3) between the drain region (22) and the floating region (31) is smaller than a width of the second region (21).

Although the embodiments of the present disclosure have been described in detail, these are merely specific examples used for clarifying the technical contents of the present disclosure. The present disclosure should not be construed as being limited to these specific examples, and the scope of the present disclosure is limited by the appended claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a chip having a main surface;
a first conductive type first region formed on a surface layer portion of the main surface;
a second conductive type second region formed on a surface layer portion of the first region;
a drain region formed on a surface layer portion of the second region;
a source region formed on the surface layer portion of the first region at a distance from the second region; and
a second conductive type floating region formed in the first region at a thickness position between a bottom portion of the first region and a bottom portion of the second region and being spaced apart from the bottom portion of the second region, wherein the floating region faces the second region with a portion of the first region interposed between the floating region and the second region.

2. The semiconductor device of claim 1, wherein the floating region is spaced apart from the bottom portion of the first region.

3. The semiconductor device of claim 1, wherein the floating region is formed at a thickness position closer to the bottom portion of the second region than the bottom portion of the first region.

4. The semiconductor device of claim 1, wherein the second region is configured to expand a first depletion layer from a boundary with the first region into the first region, and
wherein the floating region is configured to expand a second depletion layer from a boundary with the first region into the first region so that the second depletion layer is connected to the first depletion layer of the second region.

5. The semiconductor device of claim 1, wherein the floating region is formed to be smaller in width than the second region.

6. The semiconductor device of claim 1, wherein an entirety of the floating region faces the second region in a plan view.

7. The semiconductor device of claim 1, further comprising a first conductive type well region formed on the surface layer portion of the first region at a distance from the second region, wherein the well region has an impurity concentration higher than that of the first region,
wherein the source region is formed on a surface layer portion of the well region.

8. The semiconductor device of claim 7, further comprising a contact region formed on the surface layer portion of the well region in a region different from the source region.

9. The semiconductor device of claim 8, wherein the floating region is formed closer to the bottom portion of the first region than a depth position of a bottom portion of the well region, without facing the well region in a direction along the main surface.

10. The semiconductor device of claim 1, further comprising a first conductive type buried region formed inside the chip so as to cross the bottom portion of the first region, wherein the buried region has an impurity concentration higher than that of the first region,
wherein the floating region is spaced apart from the buried region.

11. The semiconductor device of claim 10, wherein the buried region is formed to be larger in width than the second region.

12. The semiconductor device of claim 1, further comprising:
a gate insulating film formed on the main surface to cover a region between the second region and the source region; and
a gate electrode formed on the gate insulating film.

13. The semiconductor device of claim 12, further comprising a field insulating film formed on the main surface to cover a periphery of the drain region,
wherein the gate insulating film has a thickness smaller than a thickness of the field insulating film and is connected to the field insulating film, and
wherein the gate electrode includes a portion that is drawn from above the gate insulating film onto the field insulating film.

14. The semiconductor device of claim 1, further comprising a second conductive type separation region formed on the surface layer portion of the main surface to partition a device region in a portion of the main surface,
wherein the first region is formed on the surface layer portion of the main surface in the device region.

15. The semiconductor device of claim 14, wherein the separation region is formed in an annular shape surrounding the portion of the main surface in a plan view.

16. The semiconductor device of claim 14, further comprising a second conductive type base region formed in a region directly below the first region inside the chip,
wherein the separation region is electrically connected to the base region.

17. The semiconductor device of claim 1, wherein a distance between the drain region and the floating region is smaller than a distance between the drain region and the source region.

18. The semiconductor device of claim 1, wherein a distance between the drain region and the floating region is smaller than a width of the second region.
